(19) United States
(12) Patent Application Publication
(10) Pub. No.: US 2025/0233163 A1
(43) Pub. Date: Jul. 17, 2025

(54) HIGH LOADING ELECTRODES HAVING HIGH AREAL CAPACITY AND ENERGY STORAGE DEVICES INCLUDING THE SAME

(71) Applicants: SAMSUNG SDI CO., LTD., Yongin-si (KR); GEORGIA TECH RESEARCH CORPORATION, Atlanta, GA (US)

(72) Inventors: Seunghun Lee, Yongin-si (KR); Gleb YUSHIN, Atlanta, GA (US); Doyoub KIM, Atlanta, GA (US)

(21) Appl. No.: 19/059,197

(22) Filed: Feb. 20, 2025

Related U.S. Application Data
(63) Continuation of application No. 16/994,037, filed on Aug. 14, 2020.
(60) Provisional application No. 62/888,203, filed on Aug. 16, 2019.

(51) Int. Cl. H01M 4/80; H01G 11/24; H01G 11/52; H01G 11/66; H01M 4/02; H01M 4/04; H01M 4/131; H01M 4/133; H01M 4/38; H01M 4/505; H01M 4/525; H01M 10/0525

(52) U.S. Cl. CPC H01M 4/80; H01G 11/24; H01G 11/52; H01G 11/66; H01M 4/0435; H01M 4/131; H01M 4/133; H01M 4/38; H01M 4/505; H01M 4/525; H01M 10/0525; H01M 2004/021; H01M 2004/027; H01M 2004/028

(57) ABSTRACT

Provided is a high areal capacity loading electrode that includes: a metal current collector; and an active material layer on the metal current collector, wherein the electrode has high areal capacity loading of greater than or equal to about 2.0 mAh/cm², and the electrode is perforated with holes spaced from each other at an average distance ranging from about 70 μm to about 900 μm. An energy storage device including the high loading electrode is also provided.

### CROSS-REFERENCE TO RELATED APPLICATION

This application is a continuation of U.S. patent application Ser. No. 16/994,037, filed Aug. 14, 2020, which claims priority to and the benefit of U.S. Provisional Patent Application No. 62/888,203 filed on Aug. 16, 2019, the entire contents of which are hereby incorporated by reference.

### BACKGROUND OF THE INVENTION

### (a) Field of the Invention

The present disclosure relates to a high loading electrode having low porosity and a high areal capacity and which is capable of providing a battery having a fast charging rate and excellent stability, and an energy storage device including the same, for example, a battery.

### (b) Description of the Related Art

Owing in part to their relatively high energy densities, relatively high specific energy, light weight, and potential for long cycle-life, advanced rechargeable batteries are desirable for a wide range of consumer electronics, electric vehicles, grid storage, and other important applications.

However, despite the increasing commercial prevalence of rechargeable Li-ion batteries, further development of these batteries is needed, particularly for potential applications in battery-powered electrical vehicles, consumer electronics, and aerospace applications, among others. High areal capacity loading electrodes that additionally exhibit dense packing of an active material and thus have high volumetric capacity are important for reducing battery cost and increasing battery energy density and specific energy.

However, conventional routes to produce such electrodes typically result in significantly reduced charging and discharging rates and thus reduced power capabilities, particularly for densely packed electrodes. In addition, such electrodes often become practically difficult to handle as they often become more brittle and have a tendency to delaminate from the current collectors during cell assembling and cell operation. Furthermore, Li-ion batteries produced with such high areal capacity loading electrodes may exhibit substantially reduced cycle stability and higher probabilities for forming internal shorts.

Accordingly, there remains a need for improved batteries, components, and other related materials and manufacturing processes.

### SUMMARY OF THE INVENTION

An embodiment provides a high areal capacity loading electrode(s) having low porosity and implementing a battery having a fast charge rate and excellent stability.

Another embodiment provides an energy storage device, for example, a battery, including the electrode(s).

In an embodiment, a high areal capacity loading electrode includes: a metal current collector; and an active material layer on the metal current collector, wherein the electrode has a high areal capacity loading of greater than or equal to about 2.0 mAh/cm², the electrode is perforated with holes spaced from each other at an average distance ranging from about 70 μm to about 900 μm, and the holes have a regular hexagonal pattern.

When the high loading electrode is a negative electrode, the active material layer may include a negative active material including intercalated graphite, soft carbon, hard carbon, or a related carbon. When the high loading electrode is a positive electrode, the active material layer may include a layered lithium nickel cobalt manganese oxide (NCM), a lithium nickel cobalt aluminum oxide (NCA), or a related layered nickel-containing oxide positive active material.

In the high loading electrode, the hole may have an average depth of about 30% to about 100%, for example, about 50% to about 100%, relative to the thickness of the active material layer.

In the high loading electrode, a total volume occupied by holes in the active material layer may be about 0.1 vol % to about 8 vol % based on a total volume, 100 vol %, of the active material layer.

The positive active material layer of the high loading electrode may have porosity of about 5 vol % to about 40 vol % based on a total volume, 100 vol %, of the active material layer. When the electrode is a positive electrode, the porosity may be about 5 vol % to about 25 vol % based on a total volume, 100 vol %, of the active material layer. When the electrode is a negative electrode, the porosity may be about 15 vol % to about 35 vol % based on a total volume, 100 vol %, of the active material layer.

The active material layer of the high loading electrode may include at least two layers having different porosities.

In the high loading electrode, the holes may be perforated in a regular hexagonal pattern.

In the high loading electrode, the holes may have a cone shape. The holes may have a concave cone shape, may be a cone with a blunt end, and the base of the cone may be elliptical or circular.

The base of the cone may have a diameter of about 5 μm to about 300 μm, for example about 15 μm to about 200 μm.

Another embodiment provides an energy storage device including the high loading electrode, and the energy storage device may be a battery, a capacitor, or the like.

The battery may be a lithium battery including a negative electrode and a positive electrode facing each other, an electrolyte ionically coupling the negative electrode and positive electrode, and a separator electrically separating the negative electrode and the positive electrode, wherein at least one of the negative electrode and the positive electrode is an electrode including a metal current collector and an active material layer on the metal current collector, the electrode has high areal capacity of greater than or equal to about 2.0 mAh/cm², and the electrode is perforated with holes spaced from each other at an average distance ranging from about 70 μm to about 900 μm.

The high loading electrode may have low porosity, a fast charging rate, excellent stability, and a high areal capacity to provide an energy storage device including the electrode.

### BRIEF DESCRIPTION OF THE DRAWINGS

The accompanying drawings are provided to aid in the description of embodiments of the present invention, are provided for illustrative purposes only, and are not limited thereto.

FIG. 1 is a schematic cross-sectional perspective view of a lithium battery according to an embodiment.

FIG. 2A is a schematic view of a roller used for manufacturing a perforated electrode, FIG. 2B is a schematic view of a track used for manufacturing a perforated electrode, and FIG. 2C is a schematic view of a template used for manufacturing a perforated electrode.

FIGS. 3A to 3C are SEM images of the electrodes according to Preparation Example 1a, Preparation Example 1b, and Preparation Example 1c, respectively.

FIGS. 4A and 4B are SEM images of the electrodes according to Preparation Examples 2a and 2b, respectively.

FIGS. 5A to 5C are microscopic images of the electrodes according to Preparation Example 2c, Preparation Example 2d, and Preparation Example 2e, respectively, and FIG. 5D shows a different magnification of the electron microscope image of the electrode according to Preparation Example 2e.

FIG. 6A is a SEM image of an electrode according to Preparation Example 3, and FIG. 6B is a different magnification of the image.

FIG. 7 is a SEM image of the electrode according to Preparation Example 4b.

FIG. 8A shows a result of an immersion test of the electrodes according to Preparation Example 1d, Preparation Example 1f, and Preparation Example 1g, FIG. 8B shows a result of an immersion test of the electrode according to Preparation Example 2f and Preparation Example 2g, and FIG. 8C shows a result of an immersion test of the electrodes according to Preparation Example 2h.

FIG. 9 is a schematic view of a symmetric cell used for electrochemical impedance spectroscopy (EIS) measurements.

FIGS. 10A to 10D show results of rate capabilities experiments of half cells including electrodes according to Preparation Example 1b, Preparation Example 1c, Preparation Example 1d, and Preparation Example 1e, respectively.

FIG. 11 shows an experiment result of a half cell including an electrode according to Preparation Example 2i.

FIG. 12 shows an experiment result of a half cell including an electrode according to Preparation Example 3.

### DETAILED DESCRIPTION OF THE EMBODIMENTS

Hereinafter, some embodiments of the present invention will be described with reference to related drawings. The term “embodiments of the invention” does not require that all embodiments of the invention include the discussed feature, advantage, process, or mode of operation, and alternate embodiments may be devised without departing from the scope of the invention. Additionally, well-known elements of the invention may not be described in detail or may be omitted so as not to be obscure other more relevant details.

This description is provided to enable any person skilled in the art to make or use embodiments of the present invention. It will be appreciated, however, that the present invention is not limited to the particular formulations, process steps, and materials disclosed herein, as various modifications to these embodiments will be readily apparent to those skilled in the art. That is, the generic principles defined herein may be applied to other embodiments without departing from the spirit or scope of the invention.

While the description below may describe certain examples in the context of Li and Li-ion batteries, it will be appreciated that various aspects may be applicable to other rechargeable and primary batteries (for example, Na-ion, Mg-ion, other metal-ion batteries, alkaline batteries, and the like). Further, while the description below may also describe certain examples of the material formulations for several specific types of common positive electrode materials (for example, lithium nickel cobalt aluminum oxide (NCA) or lithium nickel manganese cobalt oxide (NMC)) and negative electrodes (for example, graphite or silicon-graphite mixtures), it will be appreciated that various aspects may be applicable to various other electrode materials.

Any numerical range described herein with respect to any embodiment of the present invention is intended not only to define the upper and lower bounds of the associated numerical range, but also as an implicit disclosure of each discrete value within that range in units or increments that are consistent with the level of precision by which the upper and lower bounds are characterized. For example, a numerical distance range from 5 μm to 200 μm (i.e., a level of precision in units or increments of ones) encompasses (in μm) a set of [5, 6, 7, 8, 9, 10, . . . , 199, 200], as if the intervening numbers 6 through 199 in units or increments of ones were expressly disclosed. In another example, a numerical percentage range from 0.01% to 10.00% (i.e., a level of precision in units or increments of hundredths) encompasses (in %) a set of [0.01, 0.02, 0.03, . . . , 9.99, 10.00], as if the intervening numbers between 0.01 and 10.00 in units or increments of hundredths were expressly disclosed. Hence, any of the intervening numbers encompassed by any disclosed numerical range are intended to be interpreted as if those intervening numbers had been disclosed expressly, and any such intervening number may thereby constitute its own upper and/or lower boundary of a sub-range that falls inside of the broader range. Each sub-range (for example, each range that includes at least one intervening number from the broader range as an upper and/or lower boundary) is thereby intended to be interpreted as being implicitly disclosed by virtue of the express disclosure of the broader range.

As used herein, the “interval” means a distance between the center of a hole and the center of another hole that is closest thereto. In addition, as used herein, “diameter” refers to a length of the longest axis passing through the center in a circle or ellipse. Further, as used herein, “depth” is expressed as 100% from the surface of the active material layer to the base in contact with the current collector.

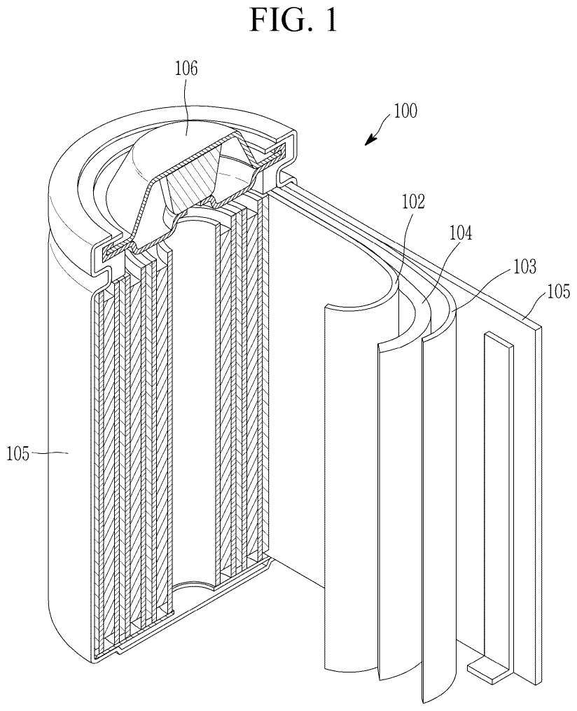

FIG. 1 is a schematic cross-sectional perspective view of a metal ion battery (e.g., a lithium-ion battery) that may be applied according to an embodiment. A cylindrical battery is shown in FIG. 1 for illustration purposes, but other types of arrangements, including prismatic or pouch (laminate-type) batteries, may also be used as desired. The battery 100 includes a negative electrode 102, a positive electrode 103, a separator 104 interposed between the negative electrode 102 and the positive electrode 103, an electrolyte (not shown) impregnating the separator 104, a battery case 105, and a sealing member 106 sealing the battery case 105.

Conventional electrodes utilized in Li-ion batteries are typically produced by: (i) formation of a slurry including active materials, conductive additives, binder solutions and, in some cases, a surfactant or other functional additives; (ii) casting the slurry onto a metal foil (for example, a Cu foil for most negative electrodes and an Al foil for most positive electrodes); (iii) drying the casted electrodes to completely evaporate the solvent; and (iv) calendaring (densification) the dried electrodes by pressure rolling. In case of thicker electrodes that exhibit relatively high areal capacity, calendaring may be conducted multiple times in order to achieve low porosity and a high volume-fraction of active materials and thus high volumetric capacity (for example, more than about 600 mAh/cm³).

Batteries are typically produced by: (i) assembling/stacking (or rolling into a so-called jelly roll) the negative electrode/separator/positive electrode/separator sandwich; (ii) inserting the stack (or jelly roll) into the battery housing (casing); (iii) filling an electrolyte into the pores of the electrodes and the separator (and also into the remaining areas of the casing) (often under vacuum); (iv) pre-sealing the battery cell (often under vacuum); (v) conducting so-called “formation” cycle(s) where the battery is slowly charged and discharged (typically one or more times); and (vi) removing typically formed gases and sealing the cell and shipping it to customers. Conventional positive electrode materials utilized in Li-ion batteries include but are not limited to lithium cobalt oxide (LCO), lithium nickel cobalt aluminum oxide (NCA), lithium nickel manganese cobalt oxide (NMC), lithium manganese oxide (LMO), lithium iron phosphate (LFP), among others. Polyvinylidene fluoride, or polyvinylidene difluoride (PVDF), is the most common binder used in these electrodes. Carbon black and carbon nanotubes are the most common conductive additive used. Conventional negative electrode materials utilized in Li-ion batteries include but are not limited to synthetic or natural graphite, graphite mixtures with silicon, silicon oxides, or silicon-metal alloys (where graphite-silicon or silicon-containing compositions are often carbon coated), lithium titanate (LTO), and others. PVDF and carboxymethyl cellulose (CMC) are the two most common binders used in these electrodes. Carbon black and carbon nanotubes are the most common conductive additive used in these electrodes.

In order to reduce battery manufacturing cost and reduce a fraction of inactive materials such as current collectors, separators and the like, it may be highly advantageous to produce relatively thick and dense electrodes with high areal capacity (hereinafter, referred to as “areal capacity loading”). It may be further advantageous for such electrodes to remain relatively dense with the remaining porosity in the electrode in the range from about 10 vol % to about 30 vol %. Lower porosity typically increases volumetric capacity of electrodes and thus battery energy density. However, too low porosity may reduce power density of the batteries (rate capability of electrodes) due to slower transport of Li ions during charging or discharging as the amount of highly ionically conductive electrolyte filling the pores would be reduced. In addition, too low porosity and too low volume fraction of the electrolyte that fills such pores when electrodes are assembled in a battery may negatively impact cell cycle stability because a portion of the electrolyte decomposes during cycling and may plug some of the remaining pores, reducing the porosity and increasing resistance during cycling to the undesirably high level. Too high porosity may be undesirable because it typically requires a larger fraction of relatively expensive electrolyte and because it typically reduces energy density of the cell. The overall porosity in each electrode may be optimized for a particular cell design and application. Thicker electrodes or electrodes with higher areal capacity loadings often require a larger fraction of pores, which may be undesirable.

An embodiment of the present disclosure provides configurations and methodologies that may enable one to achieve a higher power density with a smaller total volume of the pores in the electrode and a reduced amount of electrolyte needed for a cell without sacrificing important battery characteristics, such as power and cycle life, while using conventional slurry and coating equipment.

Successful fabrication and the use of the high loading electrode having high areal capacity (hereinafter, also referred to as “electrode” or “high areal capacity loading electrode”) that additionally exhibits dense packing of the active material and thus high volumetric capacity may be important for reducing battery cost and increasing battery energy density and specific energy. However, conventional electrodes typically suffer from significantly reduced charging and discharging rates and thus reduced power capabilities, particularly for densely packed electrodes. In addition, such conventional electrodes often become practically difficult to handle as they often become more brittle and may have a tendency to delaminate from the current collectors during cell assembling and cell operation. Furthermore, Li-ion batteries produced with such high areal capacity loading electrodes may exhibit substantially reduced cycle stability and higher probabilities for forming internal shorts.

The present disclosure may allow one to overcome some of the above-discussed challenges associated with using dense high areal capacity loading electrodes.

Prior studies have demonstrated an opportunity to laser micro-machine straight holes (typically slit-shaped) into the electrodes to reduce average diffusion time for Li ions from the electrolyte into the electrode. The electrodes have typically been assumed to be rather uniform. An average diffusion time is known to be proportional to a square of the average diffusion distance in uniform materials. As such, in order to reduce diffusion distance in, say, a substantially 100-micron thick electrodes, in prior studies researchers laser micro-machined a cross-pattern of parallel (and perpendicular), closely spaced (for example, 100 microns from each other or less), deep (to near 100% of the electrode depth) lines (for example, about 15 micron wide) into the NCM electrodes. However, such an approach consumes a significant volume fraction of active material (for example, 15% to 30%), which reduces volumetric energy density of the electrode. In addition, this approach substantially increases cell fabrication and active material costs since a significant fraction of the material is lost. Furthermore, such electrodes would then require a significantly higher fraction of rather expensive electrolyte, which undesirably increases cell fabrication cost further. As such, such an approach may become rather useless in most applications that demand high energy density or reduced cost. In addition, such patterning may induce significant damage to the electrode affecting a very large fraction of NCM particles. Such damage may typically affect long-term cycle stability of electrodes, particularly at elevated temperatures, and similarly may make this approach not practical in most applications that demand good cycle stability (for example, in excess of 500 to 1000 cycles to 100% depth of discharge at room temperature or at 40° C.). In most prior studies, the electrodes are not densified to a significant degree where less than about 30% or desirably about 15% to about 20% of pores remain in the electrode after calendaring.

While less dense electrodes may be easier to micro-machine due to smaller contact between particles and higher thermal resistance of laser-induced heat, this approach may become not practical in Li-ion battery applications because less dense electrodes typically reduce volumetric electrode capacity further and typically increase battery price. In most prior art, the electrode was not a high loading electrode, and it is unclear whether the above approach was successful, did not cause delamination, and did not cause other damage to the electrode. While thinner electrodes are typically much easier to laser micro-machine because less energy is needed for machining and less damage may be done to the electrodes, thinner electrodes may also be less attractive for Li-ion batteries and their rate capability may often be sufficiently good already. Finally, most prior studies conducted laser micro-machining on manganese (Mn) including positive electrodes such as NCM or on cobalt (Co) including positive electrodes such as NCM or LCO. Further, it may still remain unclear if Mn-free positive electrodes such as aluminum-containing NCA, lithium nickel oxide doped or coated with other metals, metal oxides, or Co-free positive electrodes would be similarly machinable and would exhibit similar improvements in rate capability. For example, if a spattered electrode material is not re-attached on nearby particles, pores may be blocked. Similarly, it was rather unclear if full cells with laser micro-machined electrodes would not suffer from premature failures (for example, due to metal leakage into the electrolyte near the damaged areas that would induce SEI growth or other undesirable side effects).

In addition, the calendered electrode has higher density (porosity: 9%) of the upper layer near the surface in contact with the electrolyte as compared with the lower layer (porosity: 14%) near the current collector. While such measurements confirmed the presence of a denser layer near the electrode surface, a difference in the estimated porosity may not explain the significantly faster Li diffusion in the laser micro-machined electrodes. An image contrast in the tomography studies mostly comes from heavier NCA particles, while the electrode binder and conductive additives remain largely invisible. The binder mixed with conductive additives in the very upper layer of such an electrode may nearly close a significant portion of the remaining pores, creating a serious bottleneck for the top-down lithium ion diffusion.

In this disclosure, there are proposed multiple methods that enable a substantial boost in rate performance and improved cycle stability in dense high areal capacity positive electrodes and negative electrodes without sacrificing less than or equal to 8%, for example, less than or equal to about 5%, less than or equal to about 2%, less than or equal to about 1%, or less than or equal to about 0.2% of active material and without requiring greater than about 4.0% of additional electrolyte.

Also, in an embodiment, the practically attainable volumetric capacity of the electrodes may not decrease but rather may increase, which may be very important for Li battery (for example, Li-ion battery) applications. Since a very small fraction of the active material is removed, the damage to the electrode active material may be dramatically reduced to a level where it may not negatively affect cell performance to a significant degree, and the cell performance may be enhanced.

In an embodiment, the electrode includes a metal current collector and an active material layer disposed on the metal current collector, wherein the electrode has an areal capacity of greater than or equal to about 4 mAh/cm², for example, greater than or equal to about 5 mAh/cm², greater than or equal to about 6 mAh/cm², greater than or equal to about 7 mAh/cm², or greater than or equal to about 8 mAh/cm². In an embodiment, the electrode may have an areal capacity of less than or equal to about 50 mAh/cm², less than or equal to about 45 mAh/cm², or less than or equal to about 40 mAh/cm².

The electrode includes a plurality of holes and the holes may have spacing between the holes of greater than or equal to about 70 μm, greater than or equal to about 100 μm, greater than or equal to about 150 μm, or greater than or equal to about 250 μm and less than or equal to about 900 μm, less than or equal to about 800 μm, less than or equal to about 700 μm, less than or equal to about 600 μm, or less than or equal to about 450 μm.

The electrode may be perforated so that the holes are arranged in a regular hexagonal pattern.

In an embodiment, the active material layer of the electrode includes an active material capable of reversibly intercalating and deintercalating lithium ions, the active material layer may include intercalation-type graphite or soft carbon, hard carbon, or a related carbon-including negative active materials when the electrode is a negative electrode, and the active material layer includes layered lithium nickel cobalt manganese oxide (NCM), lithium nickel cobalt aluminum oxide (NCA), or a related layered nickel-including oxide positive active materials when the electrode is a positive electrode.

In an embodiment, in the electrode, the hole may have an average depth of greater than or equal to about 30%, greater than or equal to about 35%, greater than or equal to about 40%, greater than or equal to about 45%, or greater than or equal to about 50% and less than or equal to about 100% or less than or equal to about 95% relative to the thickness of the active material layer.

In the active material layer of the electrode, a total volume occupied by holes in the active material layer may be greater than or equal to about 0.1 vol %, for example, greater than or equal to about 0.2 vol %, greater than or equal to about 0.3 vol %, greater than or equal to about 0.4 vol %, or greater than or equal to about 0.5 vol % and less than or equal to about 8 vol %, for example, less than or equal to about 7.5 vol %, or less than or equal to about 7.0 vol % based on a total volume, 100 vol %, of the active material layer.

In an embodiment, the positive active material layer of the electrode may have porosity of greater than or equal to about 5 vol %, for example, greater than or equal to about 10 vol %, or greater than or equal to about 15 vol % and less than or equal to about 40 vol %, for example, less than or equal to about 35 vol % or less than or equal to about 25 vol % based on a total volume, 100 vol %, of the active material layer.

When the electrode is a positive electrode, the porosity may be about 5 vol % to about 25 vol % based on a total volume, 100 vol %, of the active material layer. When the electrode is a negative electrode, the porosity may be about 15 vol % to about 35 vol % based on a total volume, 100 vol %, of the active material layer.

The active material layer of the electrode may include at least two layers having different porosities. In an embodiment, the porosity of the upper layer far from the current collector may be less than the porosity of the lower layer that is closer to the current collector than the upper layer.

The hole may have a cone shape. The hole may have a shape of a concave cone, and may be a cone having a blunt end. The base of the cone may be elliptical or circular. The base of the cone may have a diameter of greater than or equal to about 5 μm, greater than or equal to about 30 μm, or greater than or equal to about 50 μm and less than or equal to about 300 μm, less than or equal to about 250 μm, less than or equal to about 200 μm, less than or equal to about 150 μm, or less than or equal to about 100 μm.

In the high loading electrode, the size of the holes, shape of the holes, and spacing between the holes may be selected to increase an electrode charge capacity measured at a 1 C constant current rate by at least about 5%, relative to that of the same electrode without holes (electrode without perforations), as measured at room temperature in half cells.

In addition, in the high loading electrode, the size of the holes, shape of the holes, and spacing between the holes may be selected to increase an electrode charge capacity measured at a 2 C constant current rate by at least about 20%, relative to that of the same electrode without holes, as measured at room temperature in half cells.

In the high loading electrode, the size of the holes, shape of the holes, and spacing between the holes may be selected to increase an electrode discharge capacity measured at a 1 C constant current rate by at least about 5%, relative to that of the same electrode without holes, as measured at room temperature in half cells.

In the high loading electrode, the size of the holes, shape of the holes, and spacing between the holes may be selected to increase an electrode discharge capacity measured at a 2 C constant current rate by at least about 20%, relative to that of the same electrode without holes, as measured at room temperature in half cells.

In the high loading electrode, the size of the holes, shape of the holes, and spacing between the holes may be selected to reduce McMullin's number by at least about 5% relative to that of the same electrode without holes, when measured in a symmetric cell configuration.

The holes may be formed using a laser array. In the laser array, the laser beam may be split into an array of smaller less powerful beams to produce an array of holes in the electrode

In some embodiments, it may be desirable to use an IR femtosecond laser for the processing of the holes.

In an embodiment of the present disclosure, instead of (or in addition to) utilizing laser micro-machining for perforating a high capacity loading electrode, mechanical perforation may be utilized.

The holes may be produced through a roll-to-roll process.

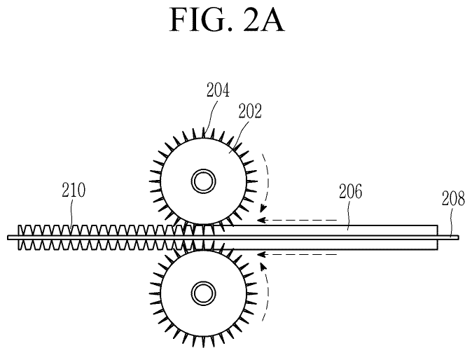

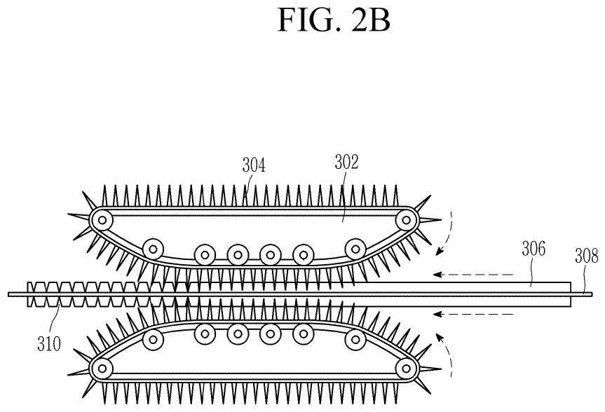

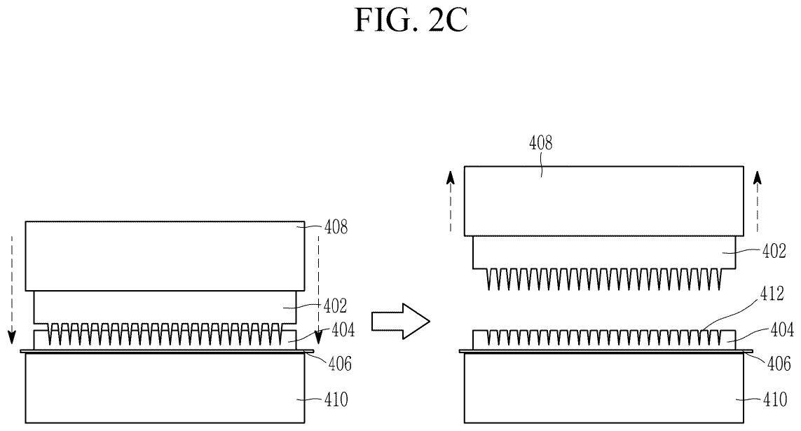

FIG. 2A is a schematic view of a roller used for manufacturing a perforated electrode. Referring to FIG. 2A, holes 210 are formed in an active material layer 206 on both surfaces of a current collector 208 while a roller 202 including needles 204 rotates.

The roller may include a microneedle array. A suitable diameter of the roller may depend on the thickness of the electrodes and the dimensions and shape of the holes that need to be introduced, but typically it may range from about 0.2 mm to about 200.0 mm. Suitable length of the microneedles (more generally, needles) may also depend on the electrode thickness, uniformity of the electrode and the roller, and also the desired hole depth, hole shape, and hole width, but it may typically range from about 0.05 mm to about 10 mm. The spacing between the neighboring microneedles may typically range from about 0.1 mm to about 3 mm, for example, from about 0.25 mm to about 2.00 mm.

In some embodiments, an array of the microneedles (more generally, needles) may be attached to a continuous track like in a bulldozer, a tractor, or a military tank instead of the single roller in order to achieve more uniform holes, to reduce a vertical dimension of the construction, or to achieve other benefits.

FIG. 2B is a schematic view of a track used in the manufacture of a perforated electrode. Referring to FIG. 2B, a track 302 including an array of needles 304 operates to form holes 310 in an active material layer 306 deposited on both surfaces of a current collector 308.

The rollers or tracks shown in FIGS. 2A and 2B are only examples, and the rollers and tracks may be applied to perforate single-sided electrodes or both surfaces of double-sided electrodes simultaneously.

FIG. 2C is a schematic view of a template used for manufacturing a perforated electrode. Referring to FIG. 2C, a template 402 in which a needle attached to an upper support 408 is disposed applies a pressure on the electrode uniaxially to form holes or indents 412 on the active material layer 404 on a single surface of the current collector 406 fixed on a lower support 410.

The template shown in FIG. 2C is merely an example, and the template may be applied to perforate a single-sided electrode or simultaneously perforate both surfaces of a double-sided electrode.

In some embodiments, partial densification (calendaring) may be conducted before or after mechanical perforation of the electrode.

In some embodiments, holes may be produced in each surface of the electrodes without producing through holes in the current collector (e.g., Cu or Al foil). In other embodiments, holes through the whole double-sided electrodes (including the current collectors) may be made.

In some embodiments of the present disclosure, instead of removing the combination of (i) active material, (ii) conductive additives, and (iii) binder from some portion of the electrodes (for example, in a top layer, some specific patterned areas, or the like), it may be advantageous to mostly modify a portion of the binder (for example, partially carbonize it in some portion of the electrode or partially oxidize it in some portion of the electrode or both) without significantly removing a significant fraction of active material.

In an embodiment, the active material may be removed in an amount of less than or equal to about 8 vol %, less than or equal to about 5 vol %, less than or equal to about 2 vol %, or less than or equal to about 0.1 vol %. In this case the rate capabilities of the high areal capacity loading electrode may be enhanced without any substantial losses of active material particles and, in some designs, even without substantial damage to active material particles. Multiple combinations and/or variations of the hole size(s) (or hole dimensions), hole shape(s), hole spacing(s), pattern(s) of holes (for example, square/tetragonal, rectangular, centered rectangular, monoclinic, and the like), depth(s) of holes, and other hole pattern parameters, may be effectively utilized to remove the active material in an amount of less than or equal to about 8 vol %, less than or equal to about 5 vol %, less than or equal to about 2 vol %, or less than or equal to about 0.1 vol % and still attain some of the needed improvements.

In an embodiment, such binder modifications (for example, in the top layer or in specific patterned areas) may be conducted by, for example, using electromagnetic radiation, for example, visible, infrared, or UV light or their combinations produced using laser(s), photodiode(s), lamp(s), or other means such as rapid contact heating for example, during a roll-to-roll process, a batch process, or other means.

In an embodiment of the present disclosure, instead of producing the distinct holes or indentations, the upper layer (e.g., about 1% to about 25% of the electrode thickness) of the calendared (densified) electrode may be relatively uniformly and at least partially removed or modified by using electromagnetic radiation, visible, infrared, or UV light or their combinations produced using, for example, laser(s), photodiode(s), lamp(s), or other means or the like in such a way so as to enhance porosity in the upper layer of the electrode without removing more than 10 vol % of the active material in the high areal capacity loading electrodes.

The process conditions for the upper layer removal or modifications (for example, light exposure time, power density of the light, and the like) may desirably be adjusted to avoid undesirable damage to the underlayer below the upper layer (for example, the lower layer) and/or to avoid any significant (for example, more than or equal to about 3% to about 30%) reductions in the electrode mechanical strength or adhesion to the current collector.

In an embodiment of the present disclosure, the inventors conducted femtosecond laser micro-machining of areal capacity loading (e.g., more than or equal to about 5 mAh/cm²) dense positive electrodes (for example, NCM, NCA, or others) and negative electrodes (for example, graphite, graphite-Si mixtures, or others) with near-cylindrical holes of various dimensions (for example, 15 μm, 30 μm, 50 μm, or 100 μm in diameter) machined to various depths (for example, 30%, 50%, or 100%) and spaced at various distances from each other (for example, 200 μm, 250 μm, 450 μm, 700 μm, or 900 μm). The results of evaluating the performance of these electrodes are described in the examples below.

The electrode may be applied as an electrode of an energy storage device.

The energy storage device includes an electrode including a metal current collector and an active material layer disposed on the metal current collector, and the electrode has an areal capacity loading of greater than or equal to about 4 mAh/cm², for example, greater than or equal to about 5 mAh/cm², greater than or equal to about 6 mAh/cm², greater than or equal to about 7 mAh/cm², or greater than or equal to about 8 mAh/cm², and the electrode includes a plurality of holes wherein the holes may have spacing between the holes of greater than or equal to about 70 μm, greater than or equal to about 100 μm, greater than or equal to about 150 μm, or greater than or equal to about 250 μm and less than or equal to about 900 μm, less than or equal to about 800 μm, less than or equal to about 700 μm, less than or equal to about 600 μm, or less than or equal to about 450 μm.

In an embodiment, the electrode may have an areal capacity of less than or equal to about 50 mAh/cm², less than or equal to about 45 mAh/cm², or less than or equal to about 40 mAh/cm².

The energy storage device may be a battery or a capacitor.

The battery includes a positive electrode and a negative electrode facing each other, an electrolyte ionically coupling the positive and negative electrodes, and a separator electrically separating the positive and negative electrodes, wherein at least one of the positive and negative electrodes includes the electrode.

Results of the characterizations and electrochemical tests for these high areal capacity loading electrodes and comparisons of these electrodes with pristine electrodes before micro-machining show that these electrodes can improve the diffusion rate of lithium ions in a certain direction. Such results led to the inventions of several electrode designs and electrode treatment methodologies that may substantially increase performance characteristics (for example, rate, cycle stability, low temperature cycling, and the like) of cells with electrodes, where only somewhere less than or equal to about 8.00 vol % (e.g., 0.05 vol % to 2.00 vol %) of active material needs to be removed after electrode casting or calendaring.

Furthermore, in another embodiment, the disclosed electrode designs, electrode fabrication routes, and electrode treatment methodologies may increase volumetric capacity and energy density of the cells at practical charge rates (for example, from about 20 min when charged or discharged at about a 3 C current density to about 5 hours when charged or discharged at about a C/5 current density) when compared with standard electrodes.

In an embodiment, positive electrodes having high areal capacity, such as NCA, NCM, and the like, as well as negative electrodes with high areal capacity, such as graphite, graphite-silicon mixtures, graphite-silicon oxide mixtures, and the like, are laser micro-machined or perforated to induce an array of holes or grooves that are spaced less than about 3.0 mm (e.g., about 0.10 mm to about 1.5 mm) from each other in such a way so as to remove the active material in an amount of less than or equal to about 8 vol %, less than or equal to about 5 vol %, less than or equal to about 2 vol %, less than or equal to about 0.1 vol % from the electrodes.

The hole micro-machining in the electrodes may be utilized in order to enhance charging rate, increase power density, and even improve practically attainable energy density of the cells including such electrodes. Furthermore, prior to micro-machining, the electrodes may be densified to a higher degree than “regular” electrodes effectively enabling higher theoretical and practically attainable volumetric capacity (and thus energy density) with similar or faster rate capability (and thus similar or higher power density).

Hereinafter, the present disclosure is illustrated in more detail with reference to examples. However, these examples are exemplary, and the present disclosure is not limited thereto.

### PREPARATION EXAMPLES

### Preparation Example 1: Preparation of Perforated Electrode (Positive Electrode) by Laser Micro-Machining Method

A mixture of 97.55 g of LiNi_{0.88}Co_{0.1}Al_{0.02}O₂ as a positive active material, 1.25 g of polyvinylidene fluoride as a binder, and 1.2 g of carbon black as a conductive agent were mixed in 137 g of N-methylpyrrolidone with a mixer to remove air bubbles and to prepare slurry for forming a positive active material layer.

The slurry for forming the positive active material layer prepared according to the above process was coated on an aluminum foil using a doctor blade to form a positive electrode, dried at 135° C. for 3 hours, and then subjected to rolling and vacuum drying processes to form a positive electrode (loading amount: 47 mg/cm²).

Perforated positive electrodes having hole diameters, spacings, and depths as shown in Table 1 were manufactured by laser micro-processing. As the perforation method, a WS-FLEX IR femtosecond laser workstation was used. Areal capacity of the perforated positive electrodes was about 6 mAh/cm².

TABLE 1

| | Diameter | Spacing | Depth |
|---|---|---|---|
| | (μm) | (μm) | (%) |
| Preparation Example 1a | 15 | 100 | 100 |
| Preparation Example 1b | 30 | 100 | 100 |
| Preparation Example 1c | 50 | 100 | 100 |
| Preparation Example 1d | 30 | 900 | 100 |
| Preparation Example 1e | 50 | 450 | 100 |
| Preparation Example 1f | 30 | 250 | 100 |
| Preparation Example 1g | 30 | 700 | 100 |
| Comparative Example 1 (pristine) | — | — | — |

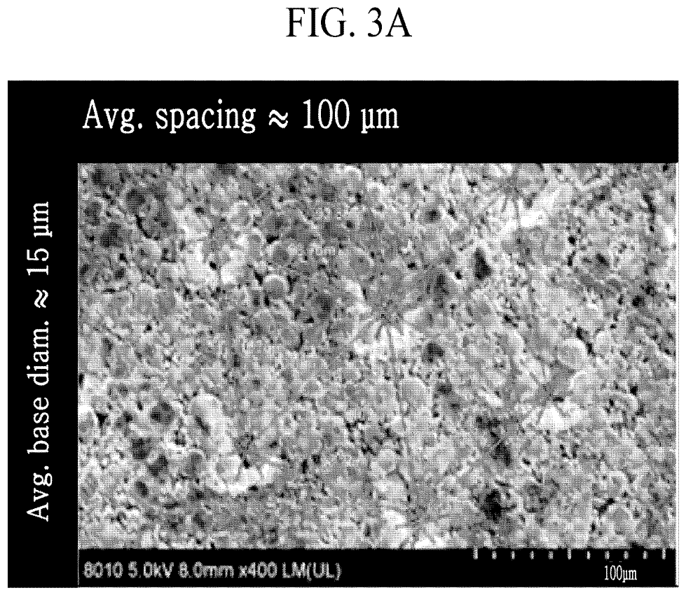

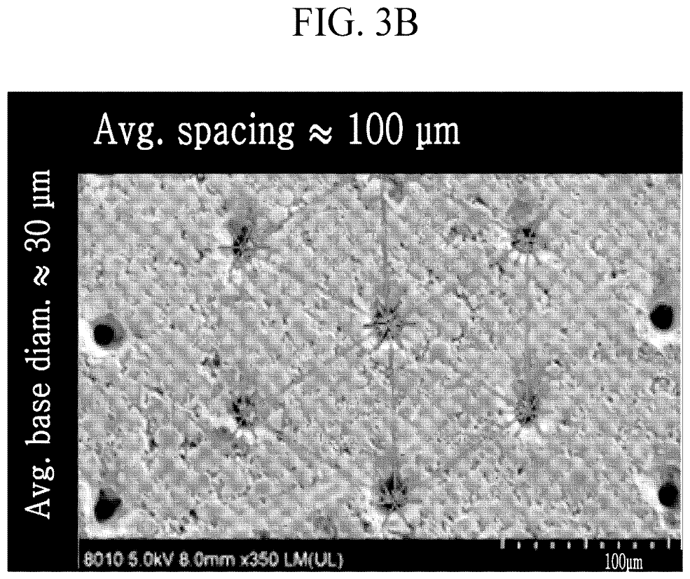

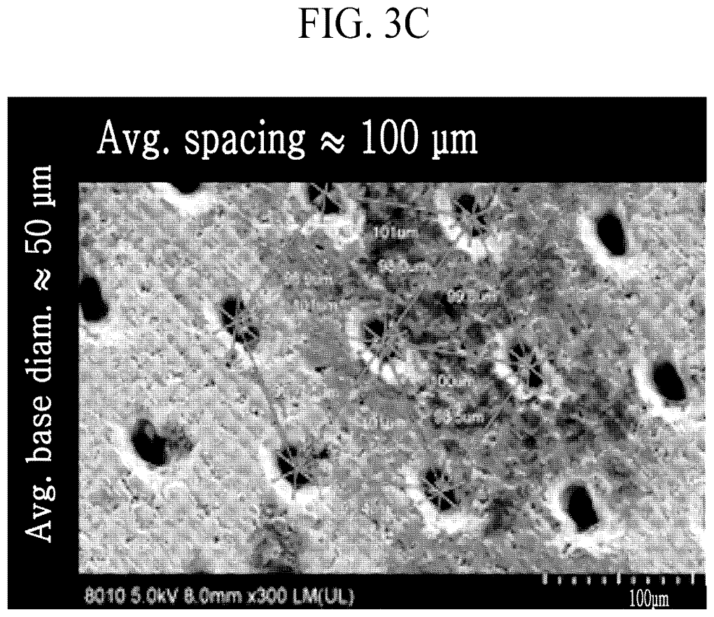

FIGS. 3A to 3C are SEM images of the electrodes according to Preparation Example 1a, Preparation Example 1b and Preparation Example 1c, respectively. FIGS. 3A to 3C show that holes having hexagonal patterns were formed on the upper surfaces of the electrodes. Small holes of 15 μm to 30 μm diameters showed shapes close to a circle, and holes of 50 μm diameters showed shapes close to an ellipse.

In Preparation Examples 1a to 1c, 5 vol % or less of the active materials were removed.

### Preparation Example 2: Preparation of Perforated Electrode (Negative Electrode) by Laser Micro-Machining Method

A mixture of 96.7 g of graphite as a negative active material, 2.3 g of a styrene butadiene rubber as a binder, and 1.0 g of carbon black as a conductive agent were mixed in 137 g of water with a mixer to remove air bubbles and to prepare slurry for forming a negative material layer.

The slurry for forming the negative active material layer prepared according to the above process was coated on a copper foil using a doctor blade to form a thin negative electrode, dried at 135° C. for 3 hours, and then subjected to rolling and vacuum drying processes to form a negative electrode (loading amount 30 mg/cm²).

Perforated negative electrodes having hole diameters, spacings, and depths as shown in Table 2 were manufactured by laser micro-processing. As the perforation method, a WS-FLEX IR femtosecond laser workstation was used. Areal capacity of the perforated negative electrodes was about 5 mAh/cm².

TABLE 2

| | Diameter | Spacing | Depth |
|---|---|---|---|
| | (μm) | (μm) | (%) |
| Preparation Example 2a | 30 | 100 | 80 |
| Preparation Example 2b | 45 | 100 | 80 |
| Preparation Example 2c | 100 | 250 | 30 |
| Preparation Example 2d | 20 | 200 | 50 |
| Preparation Example 2e | 100 | 450 | 100 |
| Preparation Example 2f | 50 | 900 | 100 |
| Preparation Example 2g | 100 | 900 | 100 |
| Preparation Example 2h | 50 | 900 | 50 |
| Preparation Example 2i | 50 | 100 | 100 |
| Comparative Example 2 (pristine) | — | — | — |

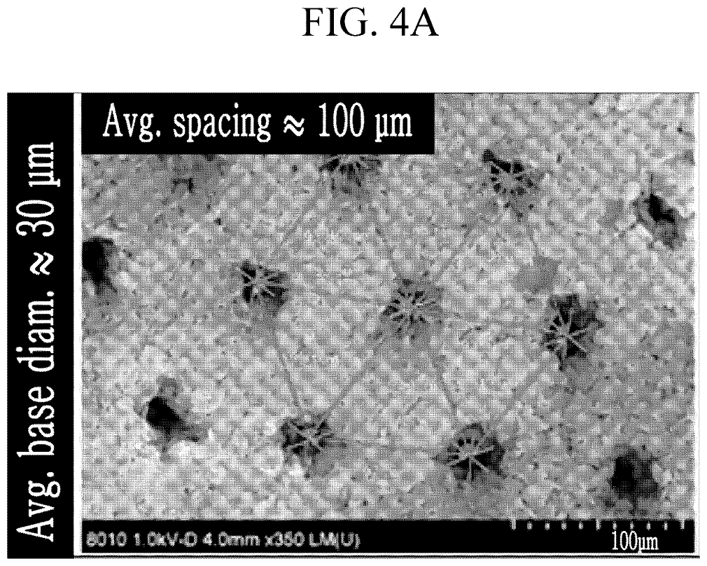

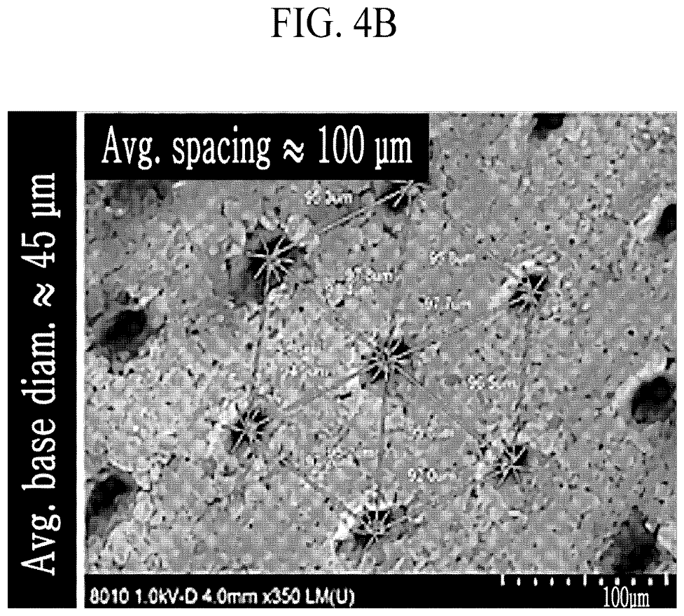

FIGS. 4A and 4B are SEM images of electrodes according to Preparation Examples 2a and 2b, respectively. The holes having a diameter of 30 μm showed shapes close to a circle, and holes having a diameter of 45 μm showed shapes close to an ellipse.

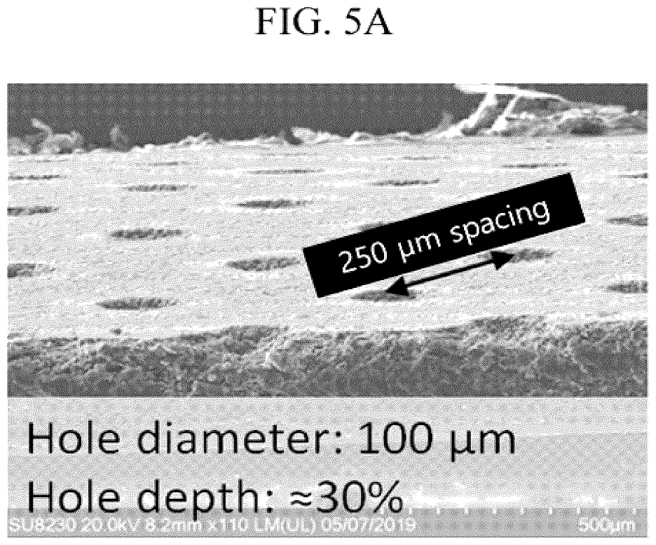

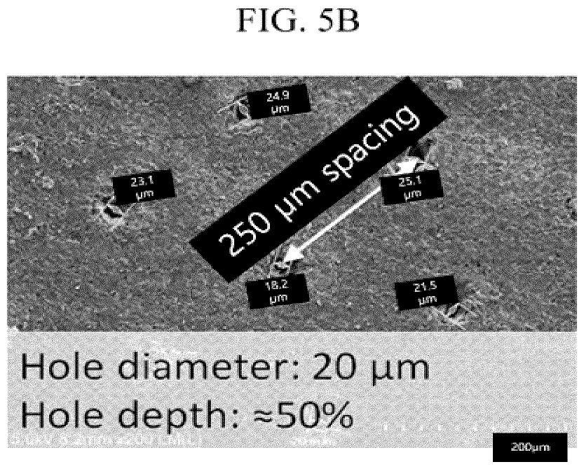

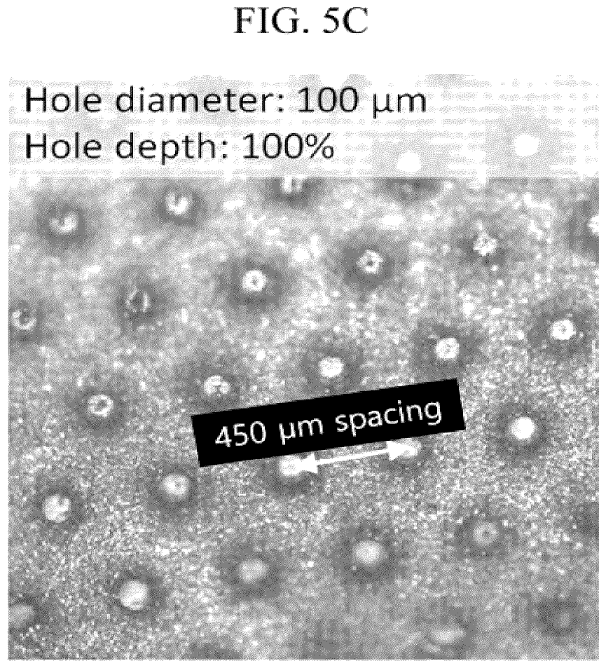

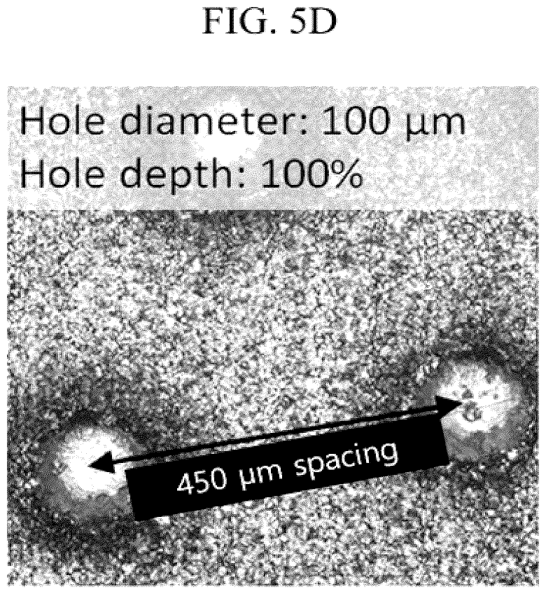

FIGS. 5A to 5C are microscopic images of the electrodes according to Preparation Example 2c, Preparation Example 2d, and Preparation Example 2e, respectively, and FIG. 5D shows a different magnification of the electron microscope image of the electrode according to Preparation Example 2e.

### Preparation Example 3: Preparation of Perforated Electrode (Positive Electrode) Processed with Rollers

A perforated positive electrode was manufactured in the same manner as in Preparation Example 1, except that holes having a diameter of 116 μm and a spacing of 1.1 μm to 1.75 μm were prepared using a roller coated with a needle array. Areal capacity of the perforated positive electrode was about 5 mAh/cm².

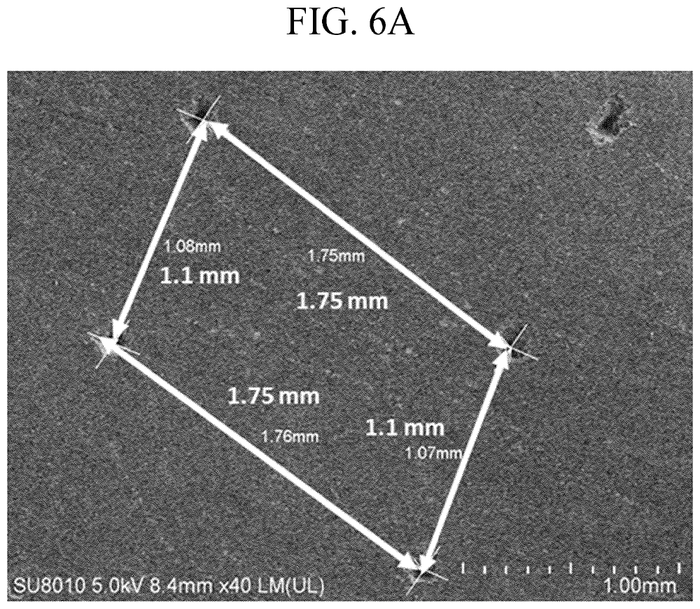

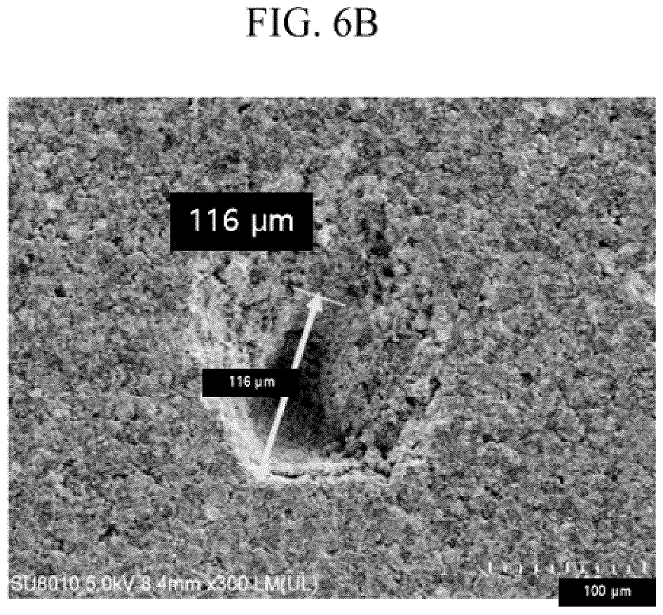

FIG. 6A is an SEM image of an electrode according to Preparation Example 3 and FIG. 6B is a different magnification of the image. The diameter and spacing of the holes of the manufactured electrode may be confirmed by the SEM image.

### Preparation Example 4: Preparation of Perforated Electrode (Negative Electrode) Processed with Microneedles

Perforated negative electrodes were manufactured in the same manner as in Preparation Example 2, except that holes having diameters and spacings as shown in Table 3 were prepared using a silicon wafer template including a microneedle array. Areal capacity of the perforated negative electrodes was about 5 mAh/cm².

TABLE 3

| | Diameter (μm) | Spacing (μm) |
|---|---|---|
| Preparation Example 4a | 100 | 900 |
| Preparation Example 4b | 100 | 700 |
| Preparation Example 4c | 200 | 900 |

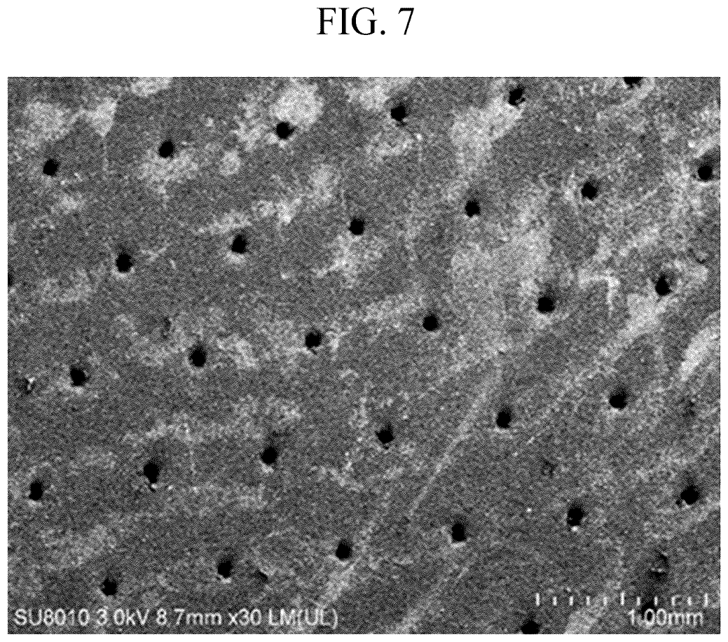

FIG. 7 is a SEM image of the electrode according to Preparation Example 4b.

### Immersion Test

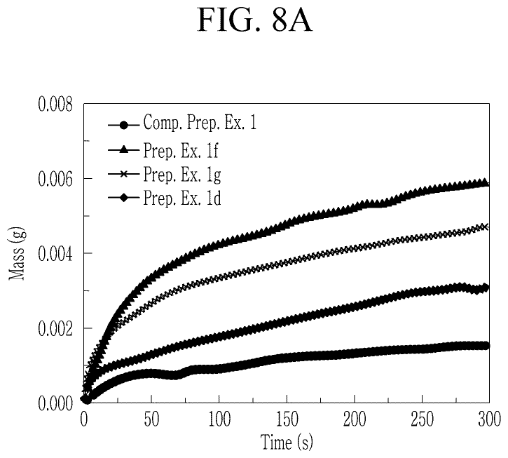

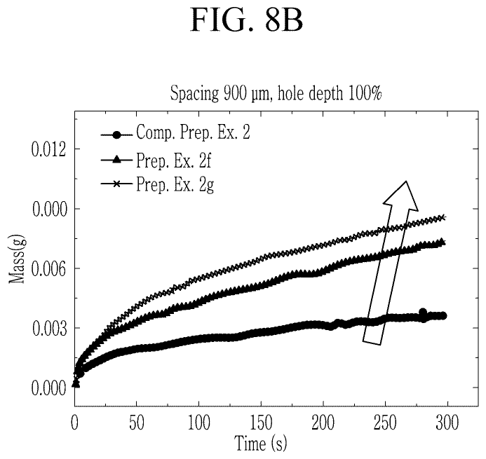

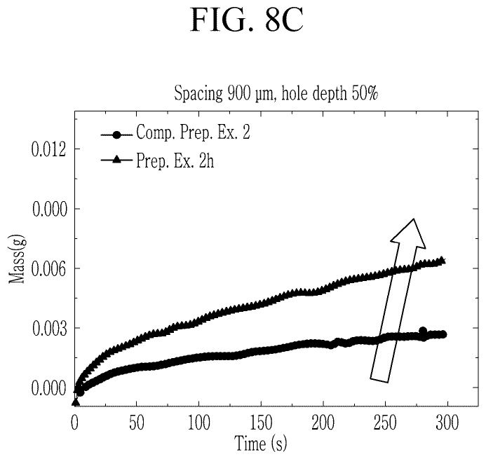

For the electrodes produced according to the same method as Preparation Example 1d, Preparation Example 1f, and Preparation Example 1g (except that the areal capacity was 5 mAh/cm² instead of 6 mAh/cm²), and the electrodes according to Preparation Example 2f and Preparation Example 2g, in order to independently confirm the faster electrolyte diffusion of the laser-perforated electrode, an immersion test was performed as follows: the electrolyte was sucked into the suspension electrodes and the weights of the sucked electrolyte were measured as a function of time. The results of the immersion test for the electrodes according to the above preparation examples are shown in FIGS. 8A to 8C.

FIG. 8A shows a result of an immersion test of the electrodes produced according to the same method as to Preparation Example 1d, Preparation Example 1f, and Preparation Example 1g (except that the areal capacity was 5 mAh/cm² instead of 6 mAh/cm²), FIG. 8B shows a result of an immersion test of the electrode according to Preparation Example 2f and Preparation Example 2g, and FIG. 8C shows a result of an immersion test of the electrodes according to Preparation Example 2h. Referring to FIGS. 8A to 8C, the electrodes according to the preparation examples exhibit much faster electrolyte penetration than the electrodes according to Comparative Preparation Example 1 and Comparative Preparation Example 2.

### Theoretical Capacity

The values (percentages) calculated based on the electrode (100%) according to Comparative Preparation Example 1 for the theoretical capacity of the electrodes (positive electrodes) having the parameters according to Table 4 are shown in Table 4.

TABLE 4

| Diameter | Spacing | Depth | Theoretical |
|---|---|---|---|
| (μm) | (μm) | (%) | capacity (%) |
| 15 | 450 | 100 | 99.6 |
| 15 | 900 | 100 | 99.9 |
| 30 | 450 | 100 | 98.4 |
| 30 | 700 | 100 | 99.3 |
| 30 | 900 | 100 | 99.6 |

The electrodes having the parameters according to Table 4 might lose 2 vol % or less, for example, 1 vol % or less, 0.5 vol % or less, or 0.1 vol % or less of the active materials.

Furthermore, if the holes were not 100% deep but only 50% deep, the material losses may be reduced further by two times. For example, the material losses may be down to about 0.05 vol % in case of the electrode having 15 μm diameter holes spaced 900 μm from each other.

And if the holes are only 30% deep, the material losses may be reduced by three times. For example, the material losses may be down to about 0.03 vol % in case of 15 μm diameter holes spaced 900 μm from each other.

If the average hole diameter is further reduced to about 5 μm, while the hole depth is kept at 30% and spacing at 900 μm, the process of hole micro-machining may result in active material losses of only about 0.003 vol %.

The tiny amount of active material removal may result in multiple benefits: faster laser processing, lower energy consumption, a smaller amount of losses, lower electrode contamination, a smaller fraction of active particles in the vicinity of the holes affected by the laser processing, and a smaller amount of extra electrolyte needed, among others.

The theoretical capacities of the electrodes (negative electrodes) having the parameters of Table 5 and a depth of 100% are calculated based on the electrode (100%) according to Comparative Preparation Example 2 (percentage), and the results are shown in Table 5.

TABLE 5

| | | Theoretical capacity | Theoretical capacity |
|---|---|---|---|
| Diameter | Spacing | of electrode having | of electrode having |
| (μm) | (μm) | cylindrical holes (%) | conical shape (%) |
| 15 | 450 | 99.9 | 99.97 |
| 15 | 100 | 98.0 | 99.32 |
| 30 | 450 | 99.6 | 99.87 |
| 30 | 700 | 99.8 | 99.94 |
| 30 | 900 | 99.9 | 99.97 |
| 30 | 250 | 98.7 | 99.56 |
| 30 | 150 | 96.4 | 98.79 |
| 30 | 100 | 91.8 | 97.28 |
| 40 | 100 | 85.5 | 95.17 |
| 50 | 100 | 77.3 | 92.45 |
| 50 | 150 | 89.9 | 96.64 |
| 50 | 250 | 96.4 | 98.79 |
| 50 | 450 | 98.9 | 99.63 |
| 50 | 700 | 99.5 | 99.85 |
| 50 | 900 | 99.7 | 99.91 |
| 100 | 900 | 98.9 | 99.63 |

The electrodes having the parameters according to Table 5 may lose 5 vol % or less of the active material. For example, 1 vol % or less, 0.5 vol % or less, or 0.03 vol % or less of the active material may be lost.

### McMullin's Number

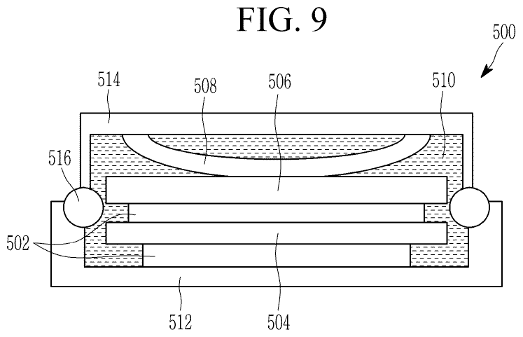

FIG. 9 is a schematic view of a symmetric cell used for electrochemical impedance spectroscopy (EIS) measurements. The symmetric cell 500 includes two electrodes 502 and a separator 504 separating the electrodes, a spacer 506, a spring 508, and an electrolyte 510, is surrounded by a coin cell base 512 and a lead 514, and is sealed with a sealing member 516. The electrode 502 includes a relatively large counter electrode and a relatively small working electrode, the separator 504 is polypropylene, and the electrolyte 510 is a solution in which 1.0 M LiPF₆ is dissolved in a mixture of ethylene carbonate and diethyl carbonate (1:1 volume ratio).

The McMullin's number was measured as described in the paper (Impedance Spectroscopy Characterization of Porous Electrodes under Different Electrode Thickness Using a Symmetric Cell for High-Performance Lithium-Ion Batteries, Nobuhiro Ogihara, et. al., J. Phys. Chem. C, 2015).

The results are shown in Table 6.

TABLE 6

| Areal capacity | | | |
|---|---|---|---|
| (mAh/cm²) | Diameter (μm) | Spacing (μm) | McMullin’s number |
| 5 | 15 | 100 | 24.4 |
| 5 | 15 | 450 | 24.6 |
| 5 | 15 | 900 | 25.0 |
| 5 | 30 | 100 | 20.5 |
| 5 | 30 | 900 | 24.5 |
| 5 | 50 | 100 | 18.7 |
| 5 | 50 | 450 | 22.7 |
| 5 | 50 | 900 | 24.1 |
| 5 | 100 | 250 | 20.9 |
| 5 | 100 | 450 | 21.4 |
| 5 | 100 | 700 | 21.8 |
| 5 | 100 | 900 | 24.0 |
| 5 | — | — | 25 |
| 6 | 100 | 250 | 19.2 |
| 6 | 100 | 450 | 20.3 |
| 6 | 100 | 700 | 20.5 |
| 6 | — | — | 23.8 |

Referring to Table 6, in the case of a perforated electrodes, the McMullin's numbers were significantly reduced compared with the electrodes without perforations. For example, the McMullin's number of the perforated electrodes may be reduced by about 1% or more, about 5% or more, about 8% or more, about 30% or more, about 40% or more, or about 75% or more compared with the electrodes without perforations.

From these results, perforated electrodes having the aforementioned capacities per area, diameters, and spacings are desirable for rapid charging and discharging.

### EXAMPLES

### Example 1: Half Cells Including Electrode of Preparation Example 1

Coin half cells were manufactured using each positive electrode according to Preparation Examples 1b to 1e and a lithium metal counter electrode as a counter electrode. A separator made of a porous polyethylene (PE) film (thickness: about 16 μm) was disposed between the positive electrode and the lithium metal counter electrode, and an electrolyte was injected to prepare a half cell. Herein, as the electrolyte, a solution containing 1.0 M LiPF₆ dissolved in a mixed solvent of ethylene carbonate and diethyl carbonate (1:1 volume ratio) was used. Rate capability was evaluated at 4.3 V to 2.8 V for the half cells manufactured as described above.

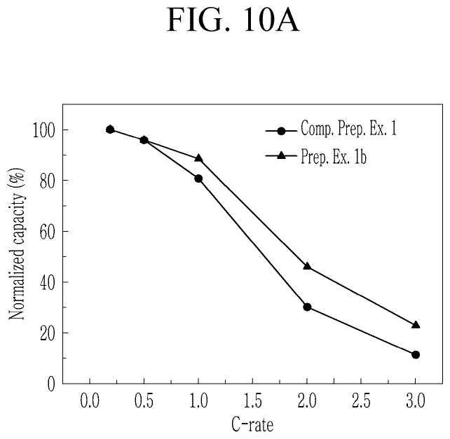

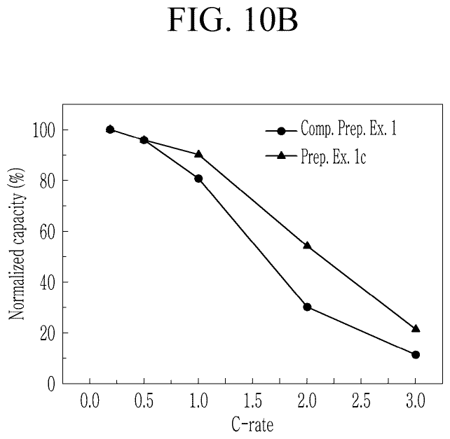

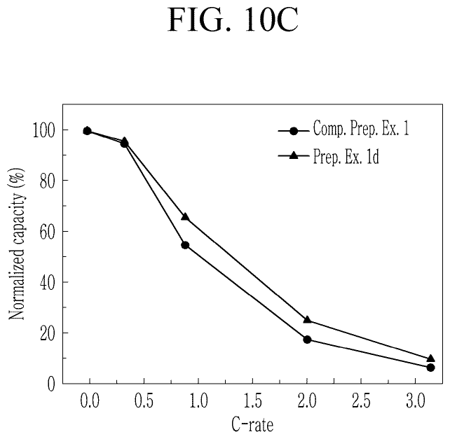

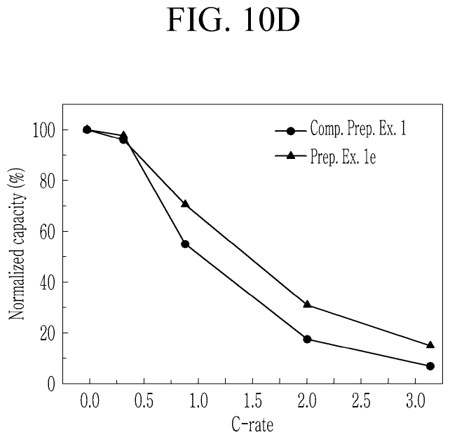

FIGS. 10A to 10D show results of rate capability experiments of half cells including electrodes produced according to the same method as Preparation Example 1b, Preparation Example 1c, Preparation Example 1d, and Preparation Example 1e, respectively (except that the areal loading was 5 mAh/cm² instead of 6 mAh/cm²). The performance of the half cell including the electrode according to Comparative Preparation Example 1 was compared together therewith.

The cells were subjected to one formation cycle at a C/10 charge rate and a C/10 discharge rate. The rest of the cycling was performed at a C/5 charge rate and different discharge rates, for example, C/5, C/2, 1 C, 2 C, or the like.

Very unexpectedly, in spite of the spacing between holes being significantly larger than the thickness of the positive electrode, substantial rate improvements may be attained, particularly noticeable at a 2 C discharge rate (charge or discharge in about 30 min) or faster rates.

Since the diffusion time (ta) is approximately proportional to a square of the diffusion distance x (t_{d}=x²/D, where D is a diffusion coefficient), an effective average diffusion coefficient of Li ion diffusion from the laser-machined holes in the direction parallel to the electrode surface should theoretically be nearly (900 μm/20*75 μm)²=36 times higher than an effective diffusion coefficient of Li ion diffusion from the top to the bottom of the electrode in order to substantially impact the rate performance. These unexpected results indicate that the top of the calendered (densified) electrode includes a very dense layer that acts as a significant bottle-neck that slows down the Li ion diffusion. It is also feasible that the laser treatment favorably modified (e.g., at least partially carbonized) the binder in the vicinity of the holes, likely also contributing to the enhanced ion diffusion.

At the discharge rates of 1 C, 2 C, and 3 C, the electrodes produced according to the same method as Preparation Examples 1b to 1e (except that the areal capacity was 5 mAh/cm² instead of 6 mAh/cm²) maintained a considerably high capacity. The capacity retention according to C-rates of the electrodes of Preparation Example 1b, Preparation Example 1c, and Comparative Preparation Example 1 are shown in Table 7.

TABLE 7

| | | | Comparative |
|---|---|---|---|
| | Preparation | Preparation | Preparation |
| C-rate | Example 1b | Example 1c | Example 1 |
| 1C | 88% | 90% | 81% |
| 2C | 46% | 54% | 30% |
| 3C | 23% | 23% | 11.2% |

### Example 2: Half Cells Including Electrode of Preparation Example 2

Coin half cells were manufactured using each negative electrode according to Preparation Examples 2i and a lithium metal counter electrode as a counter electrode. A separator made of a porous polyethylene (PE) film (thickness: about 16 μm) was disposed between the positive electrode and the lithium metal counter electrode, and an electrolyte was injected to prepare a half cell. Herein, as the electrolyte, a solution containing 1.0 M LiPF₆ dissolved in a mixed solvent of ethylene carbonate and diethyl carbonate (1:1 volume ratio) was used. Rate capability was evaluated at 1.5 V to 0.1 V for the half cells manufactured as described above.

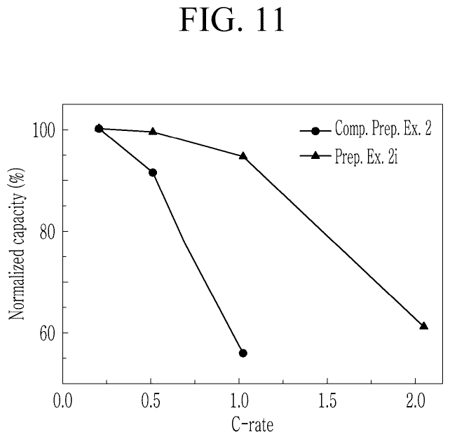

FIG. 11 shows an experiment result of a half cell including an electrode according to Preparation Example 2i. In FIG. 11, the electrode according to Comparative Preparation Example 2 and the perforated electrode including a hexagonal hole arrangement according to the electrode according to Preparation Example 2i were compared.

The cells were subjected to one formation cycle at a C/10 charge rate and a C/10 discharge rate. The rest of the cycling was performed at a C/5 charge rate and different discharge rates, for example, C/5, C/2, 1 C, and 2 C.

The perforated electrode according to Preparation Example 2i had significantly improved rate capability compared with the non-perforated electrode according to Comparative Preparation Example 2.

### Example 3: Half Cells Including Electrode of Preparation Example 3

A half cell was manufactured in the same manner as in Example 1, except that the positive electrode according to Preparation Example 3 was included. Rate capability was evaluated at 4.3 V to 2.8 V for the half cell.

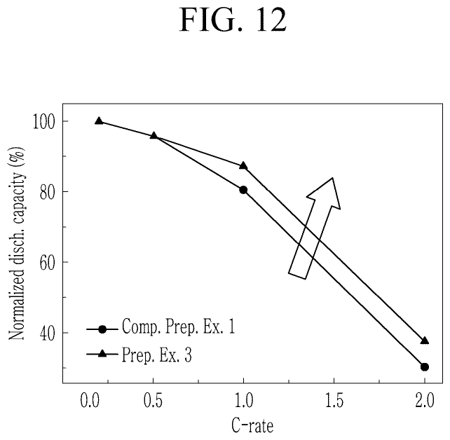

FIG. 12 shows an experiment result of a half cell including an electrode according to Preparation Example 3. For comparison, in FIG. 12, the experimental results of the half-cell using the non-perforated electrode are shown together. Referring to FIG. 12, the half-cell stability after 35 cycles was improved when the perforated electrodes were used compared with the case where the non-perforated electrodes were used.

In an embodiment, mechanical perforation with a roller coated with a needle array may reduce McMullin's numbers by 5% to 50%.

While this invention has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

### DESCRIPTION OF SYMBOLS

| | |
|---|---|
| 100: battery | 102: negative electrode |
| 103: positive electrode, | 104, 504: separator |
| 105: battery case | 106, 516: sealing member |
| 202: roller | 204, 304: needle |
| 206, 306, 404, 502: electrode | 208, 308, 406: current collector |
| 210, 310: hole | 302: track |

402: template with a needle arranged

| | |
|---|---|
| 408: upper support | 410: lower support |
| 412: hole or indent | 500: symmetric cell |
| 506: spacer | 508: spring |
| 510: electrolyte | 512: coin cell base |
| 514: lead | |

What is claimed is:

1. A high loading electrode comprising
a metal current collector, and
an active material layer disposed on the metal current collector,
the electrode has holes spaced from each other at an interval ranging from about 450 μm to about 900 μm, and
a total volume occupied by holes in the active material layer is about 0.1 vol % to about 5 vol % based on a total volume, 100 vol %, of the active material layer.

2. The high loading electrode of claim 1, wherein
wherein the electrode has an areal capacity of greater than or equal to about 4 mAh/cm2.

3. The high loading electrode of claim 1, wherein
the electrode has holes spaced from each other at an average distance ranging from about 70 μm to about 900 μm.

4. The high loading electrode of claim 1, wherein
the holes have a regular hexagonal pattern.

5. The high loading electrode of claim 1, wherein
when the high loading electrode is a negative electrode, the active material layer comprises a negative active material including intercalated graphite, soft carbon, hard carbon, or a related carbon.

6. The high loading electrode of claim 1, wherein
when the high loading electrode is a positive electrode, the active material layer comprises a layered lithium nickel cobalt manganese oxide (NCM), a lithium nickel cobalt aluminum oxide (NCA), or a related layered nickel-containing oxide positive active material.

7. The high loading electrode of claim 1, wherein the holes have a depth of about 30% to about 100%.

8. The high loading electrode of claim 1, wherein the positive active material layer has porosity of about 5 vol % to about 40 vol % based on a total volume, 100 vol %, of the active material layer.

9. The high loading electrode of claim 6, wherein
when the electrode is a positive electrode, the porosity is about 5 vol % to about 25 vol % based on a total volume, 100 vol %, of the active material layer.

10. The high loading electrode of claim 6, wherein when the electrode is a negative electrode, the porosity may be about 15 vol % to about 35 vol % based on a total volume, 100 vol %, of the active material layer.

11. The high loading electrode of claim 1, wherein the active material layer comprises at least two layers having different porosities.

12. The high loading electrode of claim 1, wherein the holes have a cone shape.

13. The high loading electrode of claim 11, wherein the holes have a concave cone shape.

14. The high loading electrode of claim 11, wherein the holes have a cone shape with a blunt end.

15. The high loading electrode of claim 11, wherein the base of the cone is elliptical or circular.

16. The high loading electrode of claim 14, wherein the base of the cone has a diameter of about 5 μm to about 300 μm.

17. An energy storage device comprising the high loading electrode of claim 1.

18. The energy storage device of claim 15, wherein the energy storage device is a battery or a capacitor.

19. The energy storage device of claim 16, wherein
the battery comprises:
a negative electrode and a positive electrode facing each other;
an electrolyte ionically coupling the negative electrode and the positive electrode; and
a separator electrically separating the negative electrode and the positive electrode,
wherein at least one of the negative electrode and the positive electrode is the high loading electrode.
